(19) United States
(12) Patent Application Publication
(10) Pub. No.: US 2013/0256022 A1
(43) Pub. Date: Oct. 3, 2013

(54) WIRING BOARD AND METHOD FOR MANUFACTURING WIRING BOARD

(71) Applicant: FUJITSU LIMITED, Kawasaki-shi (JP)

(72) Inventors: Hiroshi KOBAYASHI, Kawasaki (JP); Naoki ISHIKAWA, Nagano (JP); Satoshi EMOTO, Nagano (JP); Toru OKADA, Yokohama (JP); Takumi MASUYAMA, Kawasaki (JP)

(73) Assignee: FUJITSU LIMITED, Kawasaki-shi (JP)

(21) Appl. No.: 13/748,182

(22) Filed: Jan. 23, 2013

(30) Foreign Application Priority Data
Mar. 30, 2012 (JP) 2012-083175

(51) Int. Cl. H05K 1/02

(52) U.S. Cl. CPC H05K 1/0271
USPC 174/260; 174/250; 156/280

(57) ABSTRACT

A wiring board assembly includes: a plurality of insulating substrates of which each includes an insulating layer and a wiring layer; a wiring board that includes pads formed on the insulating substrate; and a semiconductor component that is joined on the pads by using solder bumps. The wiring board embeds a stiffening member whose thickness is thinner than that of the insulating layer and whose thermal expansion coefficient is smaller and Young's modulus is higher than those of the wiring layer and the insulating layer.

### CROSS-REFERENCE TO RELATED APPLICATION

This application is based upon and claims the benefit of priority of the prior Japanese Patent Application No. 2012-083175, filed on Mar. 30, 2012, the entire contents of which are incorporated herein by reference.

### FIELD

The embodiments discussed herein are directed to a wiring board and a method for manufacturing the wiring board.

### BACKGROUND

In recent years, various electronics are appearing in an electronic marketplace such as a portable telephone and a notebook personal computer (hereinafter, simply “PC”). However, in electronics on which consideration of reliability is not performed, when there occur distortion of thermal stress by the generation of heat during using instruments and mechanical stress by an external pressure, a stress is added to a wiring board mounted thereon and thus poor connection occurs at solder joints that join between the wiring board and semiconductor components.

Particularly, portable electronics such as a notebook PC and a portable telephone are always exposed to external stress depending on carry and operating environment. An external stress may be transmitted to a wiring board in electronics to deform the wiring board. Moreover, the deformation of the wiring board may give a bad influence to solder joints between the wiring board and semiconductor components mounted thereon to cause stripping of the solder joints. Herein, because the stripping of the solder joints may cause electrical poor connection between the wiring board and the semiconductor components, this results in the long-term degradation of reliability.

In the portable electronics, the wiring board is easily deformed by an external pressure particularly and a deforming stress of the wiring board is easily introduced into the mounting structure of the semiconductor components. Therefore, in order to raise pressure resistance and long-term reliability of the mounting structure of solder joints between the wiring board and the semiconductor components, there is known a technique for reinforcing the wiring board itself so as not to be easily deformed.

The electrical connection is performed between the wiring board and the semiconductor components by using solder joints. Furthermore, in order to ensure connection reliability, under-filling materials such as epoxy resin are filled between the wiring board and the semiconductor components to reinforce the solder joints between the wiring board and the semiconductor components from their circumferences. As a result, the wiring board raises pressure resistance and long-term reliability with respect to a stress of solder joints.

However, when the solder joints are reinforced with under-filling materials, a work burden when removing a semiconductor component from the wiring board becomes larges in case of poor connection, for example.

Therefore, there is desired the development of a mounting structure excellent in pressure resistance and repairability, which can improve pressure resistance and long-term reliability with respect to a stress of solder joints between a wiring board and semiconductor components and can simply remove a semiconductor component from the wiring board in case of poor connection, without using under-filling materials.

Therefore, the recent wiring board heightens pressure resistance with respect to stress of solder joints and thus raises long-term reliability by placing a stiffening member on the back face of a BGA (Ball Grid Array) mounting surface on which quadrangular semiconductor components are mounted.

Patent Literature 1: Japanese Laid-open Patent Publication No. 2007-088293

Patent Literature 2: Japanese Laid-open Patent Publication No. 11-040687

Patent Literature 3: Japanese Laid-open Patent Publication No. 02-079450

Patent Literature 4: Japanese Laid-open Patent Publication No. 10-056110

Patent Literature 5: Japanese Laid-open Patent Publication No. 10-150117

Patent Literature 6: Japanese Laid-open Patent Publication No. 2001-298272

Patent Literature 7: Japanese Laid-open Patent Publication No. 2008-159859

Patent Literature 8: Japanese Laid-open Patent Publication No. 2011-258836

However, the recent wiring board is difficult to ensure a space for placing a stiffening member along with the densification of surface mounted components on front and back faces of the wiring board. Therefore, pressure resistance with respect to stress of solder joints that join between the wiring board and semiconductor components is decreased and thus long-term reliability is decreased.

### SUMMARY

According to an aspect of the embodiments, a wiring board includes: an insulating substrate that includes at least one insulating layer; a wiring layer that is held in the insulating substrate and forms wiring; and a restraint member that is placed within a range of a thickness of the insulating substrate and of which a thermal expansion coefficient is smaller than thermal expansion coefficients of the wiring and the insulating substrate.

The object and advantages of the invention will be realized and attained by means of the elements and combinations particularly pointed out in the claims.

It is to be understood that both the foregoing general description and the following detailed description are exemplary and explanatory and are not restrictive of the invention.

### BRIEF DESCRIPTION OF DRAWINGS

FIG. 1 is a schematic cross-sectional view illustrating an example of a wiring board assembly according to a first embodiment;

FIG. 2 is an explanation diagram illustrating an example of an arrangement relationship of a stiffening member in the wiring board assembly according to the first embodiment;

FIG. 3A is an explanation diagram illustrating an example of a manufacturing process of a wiring board;

FIG. 3B is an explanation diagram illustrating an example of a manufacturing process of the wiring board;

FIG. 3C is an explanation diagram illustrating an example of a manufacturing process of the wiring board;

FIG. 3D is an explanation diagram illustrating an example of a manufacturing process of the wiring board;

FIG. 4 is a schematic cross-sectional view illustrating an example of a wiring board assembly according to a second embodiment;

FIG. 5 is a schematic cross-sectional view illustrating an example of a wiring board assembly according to a third embodiment;

FIG. 6 is an explanation diagram illustrating an example of an arrangement relationship of a stiffening member in the wiring board assembly according to the third embodiment;

FIG. 7A is an explanation diagram illustrating an example of a manufacturing process of a wiring board;

FIG. 7B is an explanation diagram illustrating an example of a manufacturing process of the wiring board;

FIG. 7C is an explanation diagram illustrating an example of a manufacturing process of the wiring board;

FIG. 7D is an explanation diagram illustrating an example of a manufacturing process of the wiring board;

FIG. 8A is an explanation diagram illustrating an example of a manufacturing process of the wiring board;

FIG. 8B is an explanation diagram illustrating an example of a manufacturing process of the wiring board;

FIG. 8C is an explanation diagram illustrating an example of a manufacturing process of the wiring board;

FIG. 9 is a schematic cross-sectional view illustrating an example of a wiring board assembly according to a fourth embodiment; and

FIG. 10 is an explanation diagram illustrating an example of a structure simulation result of pressure resistance with respect to stress of solder bumps.

### DESCRIPTION OF EMBODIMENTS

Preferred embodiments of the present invention will be explained with reference to accompanying drawings. The present invention is not limited to the embodiments explained below. The embodiments explained below may be appropriately combined within a scope in which the combined embodiments do not contradict each other.

### [a] First Embodiment

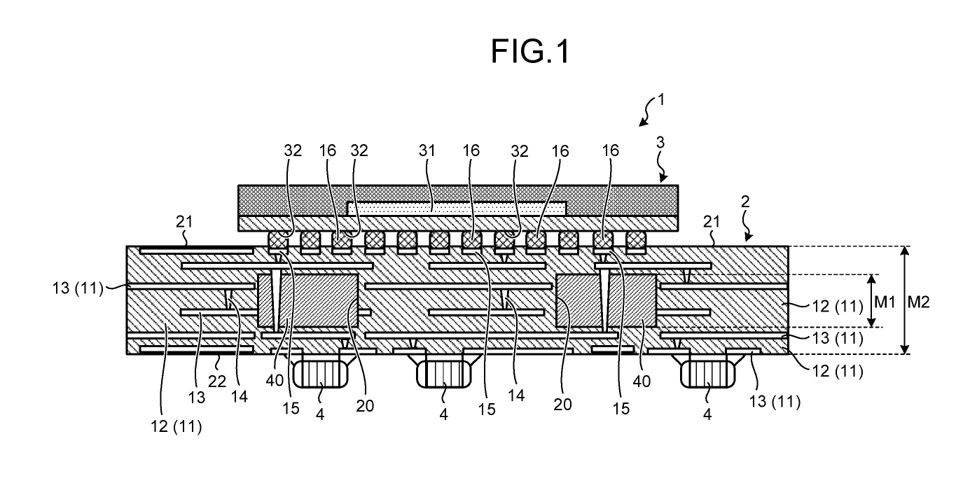

FIG. 1 is a schematic cross-sectional view illustrating an example of a wiring board assembly 1 according to the first embodiment. The wiring board assembly 1 illustrated in FIG. 1 includes a wiring board 2, a semiconductor component 3, and passive elements 4. The semiconductor component 3 is a BGA (Ball Grid Array) package that includes a semiconductor chip 31 and a plurality of electrodes 32. Moreover, the semiconductor component 3 is, for example, an MCP (Multi Chip Package) type or a CSP (Chip Size Package) type. The passive element 4 is, for example, a capacitor or a resistance element. The semiconductor component 3 is mounted on a front face 21 of the wiring board 2, for example. The passive elements 4 are mounted on a back face 22 of the wiring board 2, for example. Moreover, high-density component mounting can be performed on the front face 21 and the back face 22 of the wiring board 2.

The wiring board 2 is a multilayer wiring board in which a plurality of insulating substrates 11 are laminated. Each of the insulating substrates 11 includes an insulating layer 12 and a wiring layer 13. The insulating layer 12 is formed of, for example, FR4 (Flame Retardant Type 4) such as glass epoxy resin. The wiring layer 13 is formed of copper foil, for example. The wiring board 2 has via holes 14 that electrically connect between the different wiring layers 13. Herein, the via hole 14 electrically connects between the wiring layer 13 and the wiring layer 13 by performing copper plating on its inner circumferential wall surface. Moreover, a plurality of pads 15 connected to the semiconductor-component-side electrodes 32 are formed on the front face 21 of the wiring board 2, namely, on the BGA-mounting-surface-side wiring layer 13. The semiconductor component 3 is electrically connected to the wiring board 2 by joining the electrodes 32 to the pads 15 on the BGA mounting surface of the wiring board 2 by using solder bumps 16.

The wiring board 2 has concave portions 20 that are formed at positions extending on a straight line in a substrate laminating direction of the plurality of insulating substrates 11. The wiring board 2 embeds stiffening members 40 by placing the stiffening members 40 inside the concave portions 20. The stiffening members 40 are restraint members. The thickness M1 of the stiffening member 40 is thinner than the total thickness of the insulating substrates 11, and the stiffening member 40 is contained in insulating materials of the insulating substrates 11. Moreover, the thickness M1 of the stiffening member 40 is thinner than the thickness M2 of the wiring board 2. A material of the stiffening member 40 is, for example, alumina whose Young's modulus is higher and thermal expansion coefficient is smaller than those of the materials of the insulating layer 12 and the wiring layer 13.

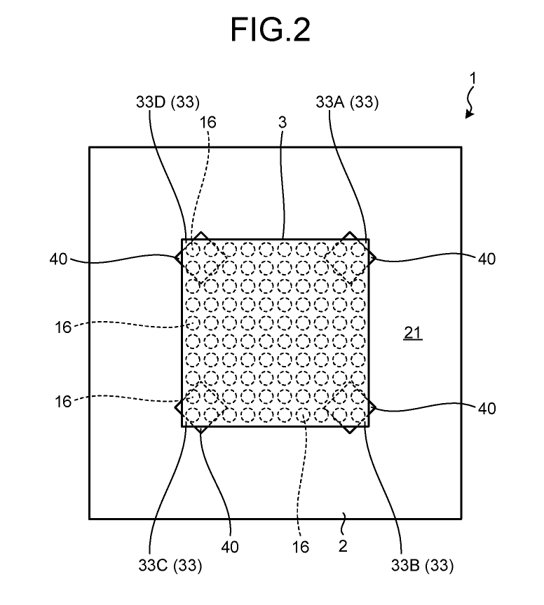

FIG. 2 is an explanation diagram illustrating an example of an arrangement relationship of the stiffening member 40 in the wiring board assembly 1 according to the first embodiment. The concave portions 20 of the wiring board 2 are formed under the pads 15 that contact the electrodes 32 located at angular portions 33 (33A to 33D) of four corners of the quadrangular semiconductor component 3. The stiffening members 40 are arranged in the concave portions 20 of the wiring board 2.

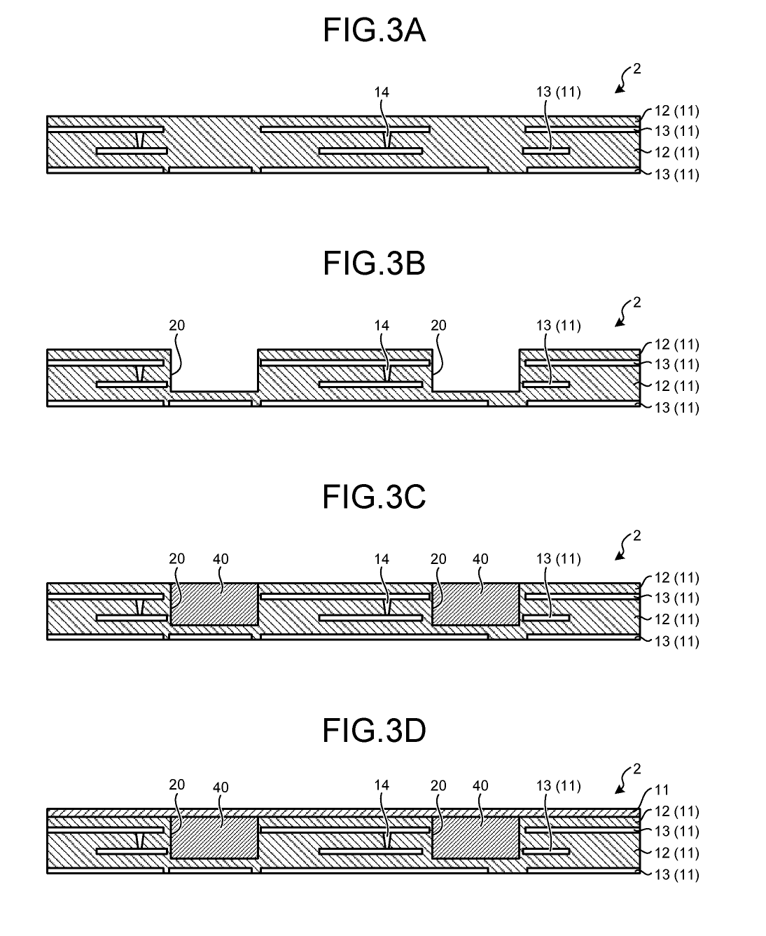

Next, a manufacturing process of the wiring board 2 of the wiring board assembly 1 according to the first embodiment will be explained. FIGS. 3A to 3C are explanation diagrams illustrating an example of a manufacturing process of the wiring board 2 of the wiring board assembly 1 according to the first embodiment. In the manufacturing process illustrated in FIG. 3A, the multilayer wiring board 2 is formed by laminating the plurality of insulating substrates 11. In the manufacturing process illustrated in FIG. 3B, the concave portions 20 are punched in predetermined parts of the front face 21 of the wiring board 2 by using a laser or the like. Herein, the predetermined parts are below the pads 15 that contact the electrodes 32 located at the angular portions 33 of four corners of the semiconductor component 3 when mounting the semiconductor component 3 on the wiring board 2.

In the manufacturing process illustrated in FIG. 3C, the stiffening members 40 are arranged in the concave portions 20 formed in the wiring board 2. Furthermore, in the manufacturing process illustrated in FIG. 3D, after the stiffening members 40 are arranged in the concave portions 20 formed in the wiring board 2, the insulating substrate 11 is laminated to cover the surfaces of the stiffening members 40 in the concave portions 20. As a result, in the manufacturing processes, the wiring board 2 that embeds the single-structure stiffening members 40 is completed.

The wiring board 2 according to the first embodiment embeds the stiffening members 40, whose Young's modulus is higher and thermal expansion coefficient is smaller than those of the insulating layer 12 and the wiring layer 13, in the concave portions 20 that are below the pads 15 that are joined to the electrodes 32 of four corners of the semiconductor component 3 by using the solder bumps 16. As a result, because the wiring board assembly 1 embeds the stiffening members 40 inside the wiring board 2, it is not necessary to provide a space on the back face 22 of the wiring board 2 on which the stiffening members are mounted. Therefore, high-density component mounting becomes possible.

In the wiring board assembly 1 according to the first embodiment, because the stiffening members 40 have materials whose Young's modulus is higher and thermal expansion coefficient is smaller than those of the insulating layer 12 and the wiring layer 13, the vicinities of the wiring-board-side pads 15 corresponding to the electrodes 32 of four corners of the semiconductor component 3 are hardened. Herein, because the vicinities of the wiring-board-side pads 15 are hardened, stress with respect to the solder bumps 16 that are joined to the pads 15 can be suppressed. As a result, the wiring board assembly 1 can raise pressure resistance with respect to the stress of the solder bumps 16 and thus can raise long-term reliability.

Moreover, in the wiring board assembly 1 according to the first embodiment, because the thermal expansion coefficient of the insulating layer 12 is larger than that of the semiconductor component 3, an impact of heat of the semiconductor component 3 can be suppressed.

Moreover, in the wiring board 2 according to the first embodiment, it has been explained that the single-structure stiffening members 40 are arranged in the concave portions 20 that are formed of the plurality of insulating substrates 11. However, the first embodiment is not limited to the single-structure stiffening member 40. The stiffening member may have a multiple structure. An embodiment for this case is explained below as a second embodiment.

### [b] Second Embodiment

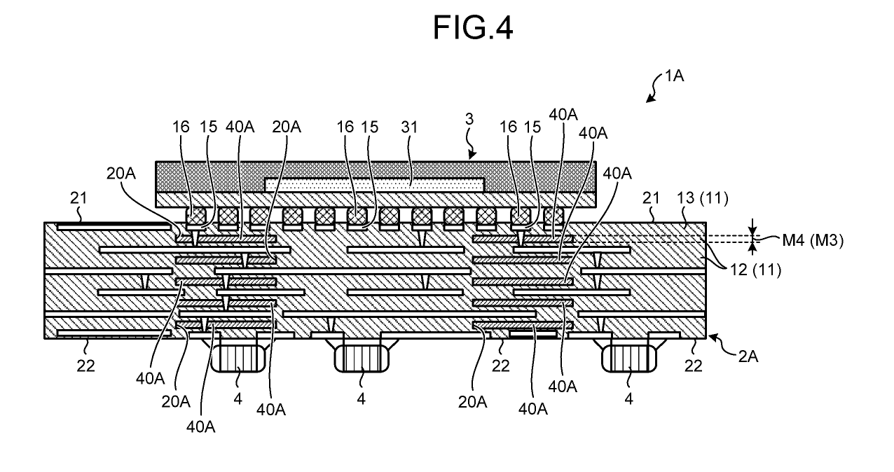

FIG. 4 is a schematic cross-sectional view illustrating an example of a wiring board assembly 1A according to the second embodiment. Herein, the same components as those of the wiring board assembly 1 illustrated in FIG. 1 have the same reference numbers, and the explanations of the same configuration and operation are omitted. Concave portions 20A are formed in a wiring board 2A illustrated in FIG. 4 for each of the insulating layers 12 in the plurality of intermediate insulating substrates 11 between the front-face-side insulating substrate 11 and the back-face-side insulating substrate 11. Stiffening members 40A are respectively arranged in the concave portions 20A. The thickness M3 of the stiffening member 40A is thinner than the thickness M4 of the insulating layer 12. A material of the stiffening member 40A is, for example, alumina whose Young's modulus is higher and thermal expansion coefficient is smaller than those of the insulating layer 12 and the wiring layer 13.

The wiring board 2A according to the second embodiment embeds the stiffening members 40A, whose Young's modulus is higher and thermal expansion coefficient is smaller than those of the insulating layer 12 and the wiring layer 13, in the concave portions 20A located below the pads 15 that are joined to the electrodes 32 of four corners of the semiconductor component 3 by using the solder bumps 16. As a result, because the wiring board assembly 1A embeds the stiffening members 40A in the respective insulating layers 12 in the intermediate insulating substrates 11, it is not necessary to provide a space on the back face 22 of the wiring board 2A on which the stiffening members are mounted. Therefore, high-density component mounting becomes possible.

Furthermore, because the wiring board assembly 1A according to the second embodiment embeds the stiffening members 40A in the respective insulating layers 12 in the intermediate insulating substrates 11, the vicinities of the wiring-board-side pads 15 corresponding to the electrodes 32 of four corners of the semiconductor component 3 are hardened. Because the vicinities of the wiring-board-side pads 15 are hardened, stresses with respect to the solder bumps 16 that are joined to the pads 15 can be dispersed and suppressed. As a result, the wiring board assembly 1A can raise pressure resistance with respect to stress of the solder bumps 16 and thus can raise long-term reliability.

Moreover, the wiring board 2A according to the second embodiment has a configuration that the stiffening members 40A are embedded in the insulating layers 12 in the intermediate insulating substrates 11 and the stiffening members 40A do not interfere with the wiring layer 13. The thickness of the stiffening member 40A is thinner than that of the insulating layer 12 for one layer, and the stiffening member 40A is contained in the corresponding insulating layer 12. Therefore, in the wiring board assembly 1A including the wiring board 2A, a degree of freedom of wiring in the wiring board 2A is increased as compared to the wiring board assembly 1 that embeds the single-structure stiffening members 40 in the wiring board 2 while interfering with the plurality of wiring layers 13. Moreover, in the manufacturing process of forming a via hole that penetrates the single-structure stiffening member 40, the via hole is preliminarily formed in the stiffening member 40. On the contrary, in the wiring board 2A according to the second embodiment, because the thickness of the stiffening member 40A is thin, a via hole can be simply formed in the stiffening member 40A by using the previously-described method of forming the via hole 14. Therefore, a degree of freedom of wiring is increased. Moreover, the surface of the stiffening member 40A may be on the same surface as a boundary surface between the insulating layer 12 and the wiring layer 13. In this case, the stiffening member 40A and the wiring layer 13 do not interfere with each other. In this configuration, if the stiffening member 40A is an electrical insulator, wiring does not have an influence on an electrical characteristic even if the wiring is formed on the stiffening member 40A.

Furthermore, in the wiring board assembly 1A, because the stiffening members 40A are arranged in the concave portions 20A in the insulating layers 12, distortion locally generated between the stiffening members 40A and the insulating layers 12 can be dispersed by the number of the stiffening members 40A as compared to the wiring board assembly 1 in which the single-structure stiffening members 40 are arranged. As a result, the wiring board assembly 1A can suppress an impact of distortion locally generated between the stiffening members 40A and the insulating layers 12 to the minimum.

In the wiring board 2A according to the second embodiment, it has been explained that the stiffening members 40A are embedded in the insulating layers 12 in the intermediate insulating substrates 11. However, this leads to the difference of thermal expansion coefficient between the stiffening members 40A and the insulating layers 12. For example, when the stiffening member 40A is formed of alumina, its thermal expansion coefficient is about 7*10⁻⁶/degrees Celsius. On the contrary, when the insulating layer 12 of the wiring board 2A is formed of FR4, an XY-direction thermal expansion coefficient is about 15*10⁻⁶/degrees Celsius and a Z-direction thermal expansion coefficient is about 50*10⁻⁶/degrees Celsius. Therefore, the difference of thermal expansion coefficient between the stiffening member 40A and the insulating layer 12 is larger. When a temperature change is caused by the change of a use environment, amounts of extension of the stiffening member 40A and the insulating layer 12 are largely different. Therefore, it may be necessary to place a buffering member that absorbs the difference of thermal expansion coefficient between the stiffening member 40A and the insulating layer 12. An embodiment for this case is explained below as a third embodiment.

### [c] Third Embodiment

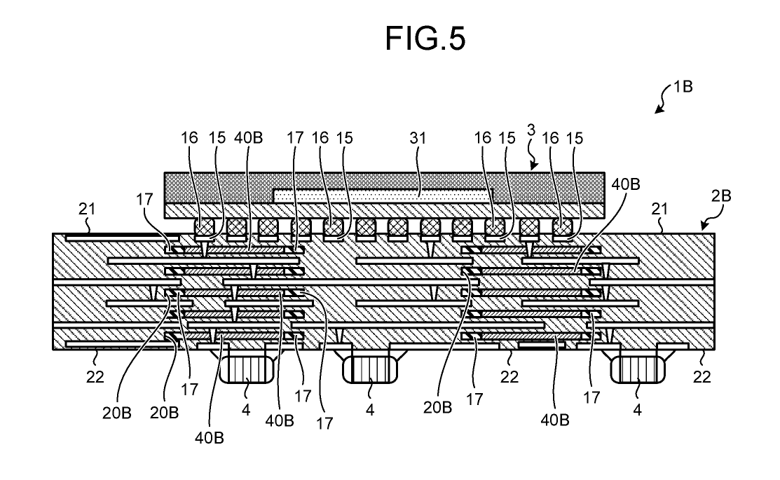

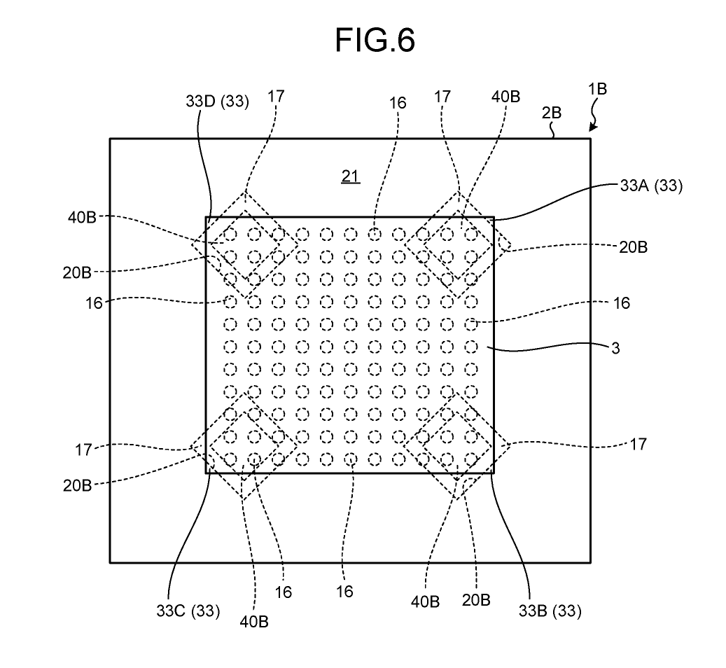

FIG. 5 is a schematic cross-sectional view illustrating an example of a wiring board assembly 1B according to the third embodiment. FIG. 6 is an explanation diagram illustrating an example of an arrangement relationship of stiffening members 40B in the wiring board assembly 1B according to the third embodiment. Herein, the same components as those of the wiring board 2A illustrated in FIG. 4 have the same reference numbers, and the explanations of the same configuration and operation are omitted. In a wiring board 2B illustrated in FIG. 5, concave portions 20B are formed in the insulating layers 12 in the intermediate insulating substrates 11. The stiffening members 40B are arranged in the concave portions 20B. Furthermore, in the wiring board 2B, buffering members 17 that have a low Young's modulus are arranged between the stiffening members 40B and the inner wall surfaces (the insulating layers 12) of the concave portions 20B, as illustrated in FIG. 6. The buffering member 17 is formed of heat-resistant silicone rubber, for example. The buffering member 17 absorbs a difference between amounts of extension of the stiffening member 40B and the insulating layer 12.

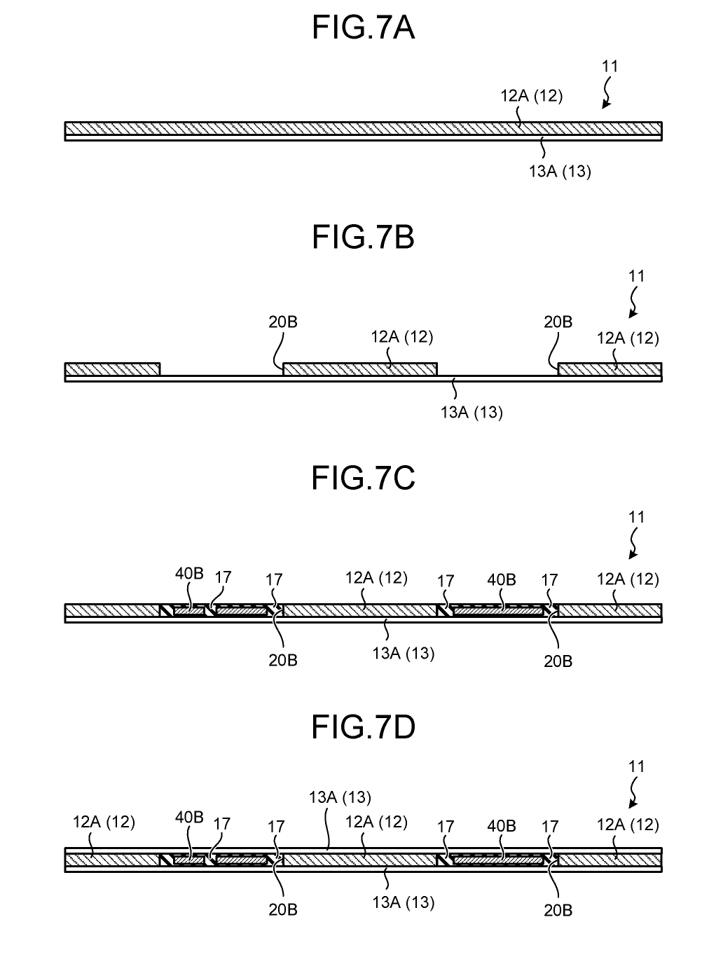

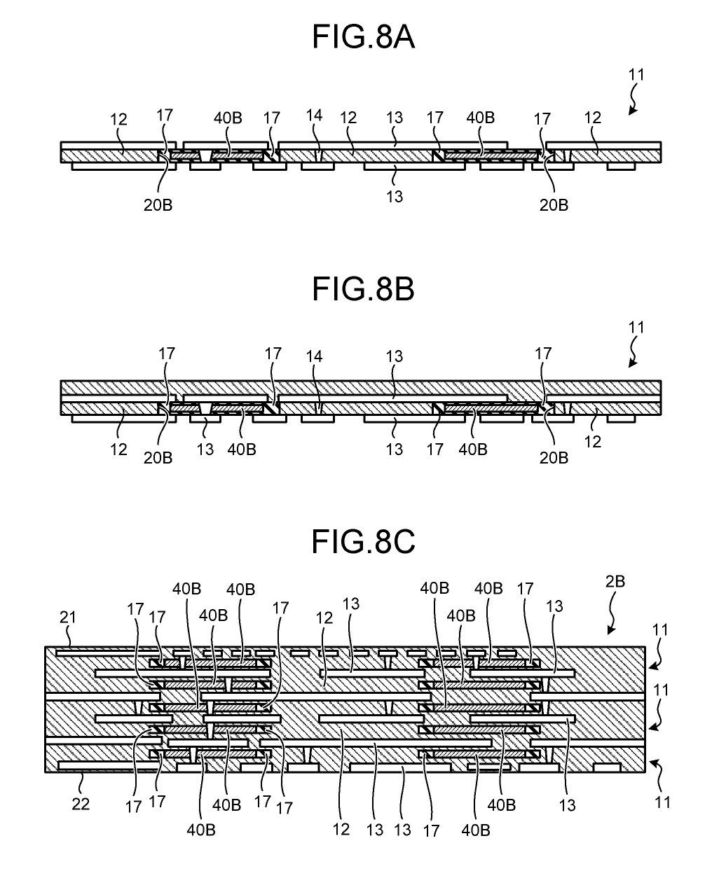

Next, a manufacturing process of the wiring board 2B in the wiring board assembly 1B according to the third embodiment will be explained. FIGS. 7A to 7D are explanation diagrams illustrating an example of a manufacturing process of the wiring board 2B. FIGS. 8A to 8C are explanation diagrams illustrating an example of a manufacturing process of the wiring board 2B. In the manufacturing process illustrated in FIG. 7A, copper foil 13A of the wiring layer 13 is bonded to prepreg 12A of the insulating layer 12. In the manufacturing process illustrated in FIG. 7B, the concave portions 20B are punched in predetermined parts of the prepreg 12A by using a laser or the like. The predetermined parts are below the pads 15 that contact the electrodes 32 located at the angular portions 33 of four corners of the semiconductor component 3 when mounting the semiconductor component 3 on the wiring board 2B.

In the manufacturing process illustrated in FIG. 7C, after applying adhesives having a low Young's modulus that act as the buffering members 17 into the concave portions 20B formed in the prepreg 12A, the stiffening members 40B having a high Young's modulus are arranged in and bonded to the concave portions 20B. In the manufacturing process illustrated in FIG. 7D, after bonding the stiffening members 40B having a high Young's modulus into the concave portions 20B, the copper foil 13A is attached to the front-face side and is integrated by press working.

In the manufacturing process illustrated in FIG. 8A, the insulating substrate 11 is completed by performing etching on the copper foil 13A of the wiring board 2B by using resist printing to form the via holes 14 in necessary parts. In the manufacturing process illustrated in FIG. 8B, the prepreg 12A is attached on the insulating substrate 11 and then the processes of FIGS. 7A, 7B, 7C, 7D, and 8A are repeated. As a result, the insulating substrates 11 are laminated.

In the manufacturing process illustrated in FIG. 8C, the multilayered wiring board 2B is completed by laminating the plurality of insulating substrates 11. As a result, the buffering members 17 and the stiffening members 40B are arranged in the concave portions 20B in the insulating layers 12 in the intermediate insulating substrates 11. Because the buffering member 17 is placed between the stiffening member 40B and the insulating layer 12, the buffering member 17 can absorb the difference of thermal expansion coefficient between the stiffening member 40B and the insulating layer 12 and can absorb the difference between amounts of extension of the stiffening member 40B and the insulating layer 12 due to the change of environmental temperature.

In the wiring board 2B according to the third embodiment, the stiffening members 40B are arranged in the concave portions 20B formed in the insulating layers 12 of the intermediate insulating substrates 11, and the buffering members 17 are arranged between the stiffening members 40B and the insulating layers 12. Furthermore, the buffering member 17 can absorb the difference between amounts of extension of the stiffening member 40B and the insulating layer 12, which is caused by the difference of thermal expansion coefficient between the stiffening member 40B and the insulating layer 12.

In the wiring board 2B according to the third embodiment, the stiffening members 40B having materials, whose Young's modulus is higher and thermal expansion coefficient is smaller than those of the insulating layer 12 and the wiring layer 13, are embedded in the concave portions 20B located below the pads 15 that are joined to the electrodes 32 of four corners of the semiconductor component 3 by using the solder bumps 16. As a result, because the wiring board assembly 1B embeds the stiffening members 40B in the insulating layers 12 in the intermediate insulating substrates 11, it is not necessary to provide a space on the back face 22 of the wiring board 2B on which the stiffening members are mounted. Therefore, high-density component mounting becomes possible.

Furthermore, in the wiring board assembly 1B according to the third embodiment, because the stiffening members 40B are embedded in the insulating layers 12 in the intermediate insulating substrates 11, the vicinities of the wiring-board-side pads 15 corresponding to the electrodes 32 of four corners of the semiconductor component 3 are hardened. Therefore, because the vicinities of the wiring-board-side pads 15 are hardened, stresses with respect to the solder bumps 16 that are joined to the pads 15 can be dispersed and suppressed. As a result, the wiring board assembly 1B can raise pressure resistance with respect to stress of the solder bumps 16 and can improve long-term reliability.

It has been explained that the wiring board 2B according to the third embodiment embeds the stiffening members 40B in the insulating layers 12 in the intermediate insulating substrates 11 so that the stiffening members 40B do not interfere with the wiring layers 13. Therefore, in the wiring board assembly 1B, a degree of freedom of wiring in the wiring board 2B is improved as compared to the wiring board assembly 1 that embeds the single-structure stiffening members 40 in the wiring board 2 while interfering with the plurality of wiring layers 13. Moreover, in the process of forming a via hole that penetrates the single-structure stiffening member 40, it is necessary to preliminarily form the via hole in the stiffening member 40. On the contrary, because the thickness of the stiffening member 40B is thinner in the wiring board 2B according to the third embodiment, a via hole can be simply formed inside the stiffening member 40B by using the previously-described method of forming the via hole 14. Therefore, a degree of freedom of wiring is improved.

In the wiring board 2B of the third embodiment, it has been explained that silicone rubber having a low Young's modulus is used as the buffering member 17 between the stiffening member 40B and the insulating layer 12. However, the buffering member may be a cavity, for example, while considering moisture.

In the previously-described wiring board 2A according to the second embodiment, it has been explained that the stiffening members 40A are arranged in the insulating layers 12 of the insulating substrates 11. However, wiring of the copper foil 13A, which is not conducted to the wiring layer 13, in the wiring layer 13 of the insulating substrate 11 may be used as the stiffening member. Herein, an embodiment for this case is explained below as a fourth embodiment.

### [d] Fourth Embodiment

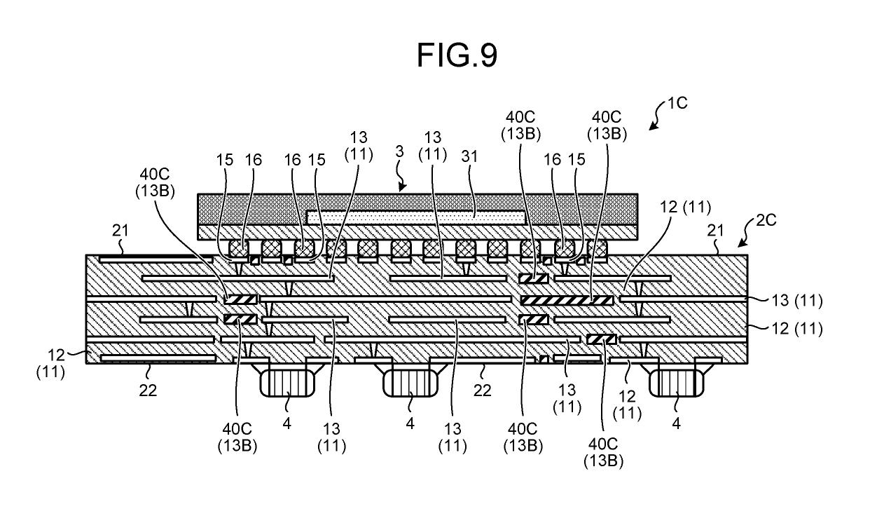

FIG. 9 is a schematic cross-sectional view illustrating an example of a wiring board assembly 1C of the fourth embodiment. The same components as those of the wiring board assembly 1A illustrated in FIG. 4 have the same reference numbers, and the explanations of the same configuration and operation are omitted. In a wiring board 2C illustrated in FIG. 9, an unconducted copper foil wire 13B in the wiring layer 13 is left by resist and is used as a stiffening member 40C for each of the wiring layers 13 in the plurality of intermediate insulating substrates 11 between the front-face-side insulating substrate 11 and the back-face-side insulating substrate 11. Moreover, the unconducted copper foil wire 13B is an unconducted wire that is not used as the wiring layer 13 and is not conducted to the wiring layer 13. Because the stiffening member 40C is the copper foil wire 13B, the stiffening member 40C has materials whose Young's modulus is higher and thermal expansion coefficient is smaller than those of the insulating layer 12. When the stiffening member 40C is the copper foil wire 13B, its thermal expansion coefficient is about 17*10⁻⁶/degrees Celsius. On the contrary, when the insulating layer 12 is FR4, its thermal expansion coefficient is about 15*10⁻⁶/degrees Celsius. The difference between thermal expansion coefficients of the stiffening member 40C and the insulating layer 12 is small.

In the wiring board 2C according to the fourth embodiment, the unconducted copper foil wire 13B, which is left as the wiring layer 13 in the intermediate insulating substrate 11 located below the pads 15 that are joined to the electrodes 32 of four corners of the semiconductor component 3 by using the solder bumps 16, is used as the stiffening member 40C. As a result, because the wiring board 2C uses the unconducted copper foil wire 13B as the stiffening member 40C, the vicinities of the wiring-board-side pads 15 corresponding to the electrodes 32 of four corners of the semiconductor component 3 are hardened. Therefore, because the vicinities of the wiring-board-side pads 15 are hardened, stresses with respect to the solder bumps 16 that are joined to the pads 15 can be dispersed and suppressed. As a result, the wiring board assembly 1C can raise pressure resistance with respect to stress of the solder bumps 16 and can raise long-term reliability.

Because the wiring board assembly 1C according to the fourth embodiment embeds the stiffening members 40C in the wiring board 2C, it is not necessary to provide a space on the back face 22 of the wiring board 2C on which the stiffening members are mounted. Therefore, high-density component mounting becomes possible.

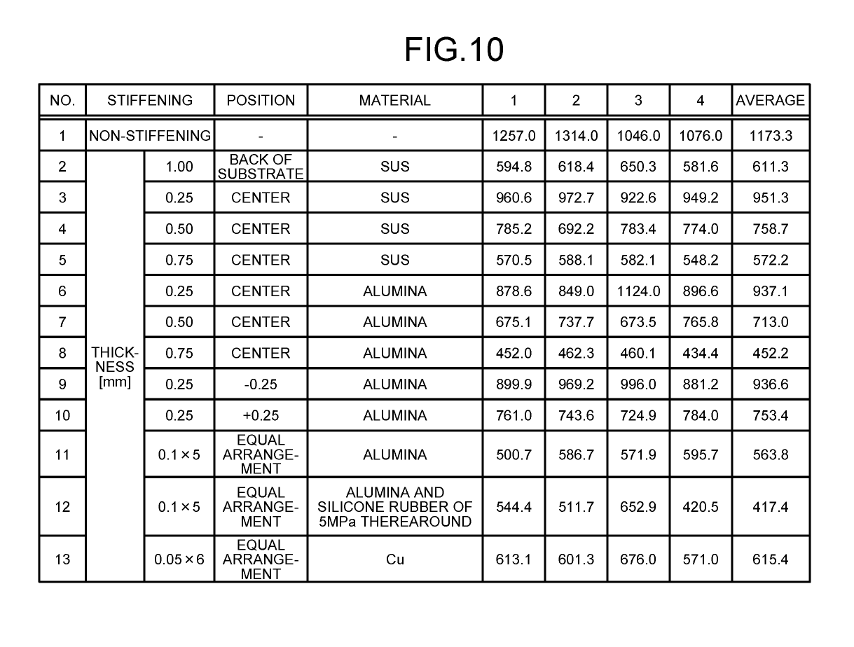

Next, structure simulations of pressure resistance with respect to stress of the solder bumps 16 of the wiring board assembly 1 (1A, 1B, 1C) according to the first to fourth embodiments have been performed. FIG. 10 is an explanation diagram illustrating an example of structure simulation results of pressure resistance with respect to stress of the solder bumps 16. In this case, as simulation conditions, the shape of the semiconductor component 3 is a square of which each side is 23 mm. The insulating substrate 11 is constituted by FR4 and is a square of which the thickness is 1.0 mm and each side is 110 mm. The solder bump 16 is constituted by SAC (Sn—Ag—Cu) solder and has a diameter of 0.4 mm and a thickness of 0.4 mm. The pitch interval of the solder bumps 16 is 0.8 mm. The shape of the stiffening member 40 is a square of which each side is 3.5 mm.

Under these simulation conditions, setting is performed to add an external force of 4 kg to the wiring board 2 of the wiring board assembly 1 and to transmit the stresses to the solder bumps 16 that are joined to the electrodes 32 of the angular portions 33 of four corners of the semiconductor component 3, and stresses with respect to the solder bumps 16 of four corners are observed. Under the conditions, target bump stresses that can be allowed with respect to the solder bumps 16 are not more than 800 MPa.

In FIG. 10, a simulation No. 1 is a simulation result of a wiring board assembly that does not include a stiffening member. Stresses transmitted to the solder bumps 16 of four corners of the semiconductor component 3 are as follows. A bump stress of a first angular portion 33A is 1257.0 MPa, a bump stress of a second angular portion 33B is 1314.0 MPa, a bump stress of a third angular portion 33C 1046.0 MPa, and a bump stress of a fourth angular portion 33D is 1076.0 MPa. Therefore, an average value of the bump stresses of the wiring board assembly of the simulation No. 1 is 1173.3 MPa.

A simulation No. 2 is a simulation result of a wiring board assembly that includes an SUS stiffening member having the thickness of 1 mm that is placed on the back face of a wiring board. A bump stress of the first angular portion 33A is 594.8 MPa, a bump stress of the second angular portion 33B is 618.4 MPa, a bump stress of the third angular portion 33C is 650.3 MPa, and a bump stress of the fourth angular portion 33D is 581.6 MPa. Therefore, because an average value of the bump stresses of the wiring board assembly of the simulation No. 2 is 611.3 MPa, the bump stresses can be suppressed to values not more than the target 800 MPa.

A simulation No. 3 is a simulation result of the wiring board assembly 1 that embeds the single-structure SUS stiffening member 40 having the thickness of 0.25 mm at the center of the wiring board 2. A bump stress of the first angular portion 33A is 960.6 MPa, a bump stress of the second angular portion 33B is 972.7 MPa, a bump stress of the third angular portion 33C 922.6 MPa, and a bump stress of the fourth angular portion 33D is 949.2 MPa. Therefore, an average value of the bump stresses of the wiring board assembly 1 of the simulation No. 3 is 951.3 MPa.

A simulation No. 4 is a simulation result of the wiring board assembly 1 that embeds the single-structure SUS stiffening member 40 having the thickness of 0.50 mm at the center of the wiring board 2. A bump stress of the first angular portion 33A is 785.2 MPa, a bump stress of the second angular portion 33B is 692.2 MPa, a bump stress of the third angular portion 33C is 783.4 MPa, and a bump stress of the fourth angular portion 33D is 774.0 MPa. Therefore, because an average value of the bump stresses of the wiring board assembly 1 of the simulation No. 4 is 758.7 MPa, the bump stresses can be suppressed to not more than the target 800 MPa. In the wiring board assembly 1 of the simulation No. 4, the bump stresses can be suppressed to not more than the target 800 MPa by using the stiffening member having a half thickness in comparison with the wiring board assembly of the simulation No. 2.

A simulation No. 5 is a simulation result of the wiring board assembly 1 that embeds the single-structure SUS stiffening member 40 having the thickness of 0.75 mm at the center of the wiring board 2. A bump stress of the first angular portion 33A is 570.5 MPa, a bump stress of the second angular portion 33B is 588.1 MPa, a bump stress of the third angular portion 33C is 582.1 MPa, and a bump stress of the fourth angular portion 33D is 548.2 MPa. Therefore, because an average value of the bump stresses of the wiring board assembly 1 of the simulation No. 5 is 572.2 MPa, the bump stresses can be suppressed to not more than the target 800 MPa. Moreover, the simulation No. 5 can obtain a stress depression effect even in comparison to the simulation No. 2 of the wiring board assembly that includes the stiffening member placed on the back face of the wiring board.

A simulation No. 6 is a simulation result of the wiring board assembly 1 that embeds the single-structure alumina stiffening member 40 having the thickness of 0.25 mm at the center of the wiring board 2. A bump stress of the first angular portion 33A is 878.6 MPa, a bump stress of the second angular portion 33B is 849.0 MPa, a bump stress of the third angular portion 33C is 1124.0 MPa, and a bump stress of the fourth angular portion 33D is 896.6 MPa. Therefore, an average value of the bump stresses of the wiring board assembly 1 of the simulation No. 6 is 937.1 MPa.

A simulation No. 7 is a simulation result of the wiring board assembly 1 that embeds the single-structure alumina stiffening member 40 having the thickness of 0.50 mm at the center of the wiring board 2. A bump stress of the first angular portion 33A is 675.1 MPa, a bump stress of the second angular portion 33B is 737.7 MPa, a bump stress of the third angular portion 33C is 673.5 MPa, and a bump stress of the fourth angular portion 33D is 765.8 MPa. Therefore, because an average value of the bump stresses of the wiring board assembly 1 of the simulation No. 7 is 713.0 MPa, the bump stresses can be suppressed to not more than the target 800 MPa.

A simulation No. 8 is a simulation result of the wiring board assembly 1 that embeds the single-structure alumina stiffening member 40 having the thickness of 0.75 mm at the center of the wiring board 2. A bump stress of the first angular portion 33A is 452.0 MPa, a bump stress of the second angular portion 33B is 462.3 MPa, a bump stress of the third angular portion 33C is 460.1 MPa, and a bump stress of the fourth angular portion 33D is 434.4 MPa. Therefore, because an average value of the bump stresses of the wiring board assembly 1 of the simulation No. 8 is 452.2 MPa, the bump stresses can be suppressed to not more than the target 800 MPa.

A simulation No. 9 is a simulation result of the wiring board assembly 1 that embeds the single-structure alumina stiffening member 40 having the thickness of 0.25 mm at a position separated by 0.25 mm from a center location of the wiring board 2 in a back-face-side direction. A bump stress of the first angular portion 33A is 899.9 MPa, a bump stress of the second angular portion 33B is 969.2 MPa, a bump stress of the third angular portion 33C is 996.0 MPa, and a bump stress of the fourth angular portion 33D is 881.2 MPa. Therefore, an average value of the bump stresses of the wiring board assembly 1 of the simulation No. 9 is 936.6 MPa.

A simulation No. 10 is a simulation result of the wiring board assembly 1 that embeds the single-structure alumina stiffening member 40 having the thickness of 0.25 mm at a position separated by 0.25 mm from a center location of the wiring board 2 in a front-face-side direction. A bump stress of the first angular portion 33A is 761.0 MPa, a bump stress of the second angular portion 33B is 743.6 MPa, a bump stress of the third angular portion 33C is 724.9 MPa, and a bump stress of the fourth angular portion 33D is 784.0 MPa. Therefore, because an average value of the bump stresses of the wiring board assembly 1 of the simulation No. 10 is 753.4 MPa, the bump stresses can be suppressed to not more than the target 800 MPa.

A simulation No. 11 is a simulation result of the wiring board assembly 1A that includes the five alumina stiffening members 40A having the thickness of 0.1 mm that are equally arranged in the wiring board 2A according to the second embodiment. A bump stress of the first angular portion 33A is 500.7 MPa, a bump stress of the second angular portion 33B is 586.7 MPa, a bump stress of the third angular portion 33C is 571.9 MPa, and a bump stress of the fourth angular portion 33D is 595.7 MPa. Therefore, because an average value of the bump stresses of the wiring board assembly 1A of the simulation No. 11 is 563.8 MPa, the bump stresses can be suppressed to not more than the target 800 MPa.

In a simulation No. 12, the five alumina stiffening members 40B having the thickness of 0.1 mm are equally arranged in the wiring board 2B. Furthermore, the simulation No. 12 is a simulation result of the wiring board assembly 1B that places the buffering member 17 formed of silicone rubber of 5 MPa between the insulating layer 12 and the stiffening member 40B according to the third embodiment. A bump stress of the first angular portion 33A is 544.4 MPa, a bump stress of the second angular portion 33B is 511.7 MPa, a bump stress of the third angular portion 33C is 652.9 MPa, and a bump stress of the fourth angular portion 33D is 420.5 MPa. Therefore, because an average value of the bump stresses of the wiring board assembly 1B of the simulation No. 12 is 417.4 MPa, the bump stresses can be suppressed to not more than the target 800 MPa.

In a simulation No. 13, the copper foil wire 13B having the thickness of 0.05 mm that is not used as the wiring layer 13 is used as the stiffening member 40C. The simulation No. 13 is a simulation result of the wiring board assembly 1C that equally arranges the six stiffening members 40C in the wiring board 2C according to the fourth embodiment. A bump stress of the first angular portion 33A is 613.1 MPa, a bump stress of the second angular portion 33B is 601.3 MPa, a bump stress of the third angular portion 33C is 676.0 MPa, and a bump stress of the fourth angular portion 33D is 571.0 MPa. Therefore, because an average value of the bump stresses of the wiring board assembly 1C of the simulation No. 13 is 615.4 MPa, the bump stresses can be suppressed to not more than the target 800 MPa.

According to the simulation results, when comparing the simulation No. 4 (No. 5) with the simulation No. 7 (No. 8), it can be confirmed that the wiring board assembly that uses alumina having a high Young's modulus as the stiffening member 40 has a high stress depression effect in comparison with SUS.

Moreover, when comparing the wiring board assembly 1 of the simulation No. 9 with the wiring board assembly 1 of the simulation No. 10, it can be confirmed that the wiring board assembly that places the stiffening member 40 at a position close to the semiconductor component 3 and the BGA mounting surface (the front face 21) has a high stress depression effect.

Moreover, when comparing the wiring board assembly 1 of the simulation No. 7 with the wiring board assembly 1A of the simulation No. 11, the thickness of the five stiffening members 40A and the thickness of the single-structure stiffening member 40 are the same and are 0.50 mm. However, it can be confirmed that the wiring board assembly of the simulation No. 11 that equally arranges the five stiffening members 40A in the insulating substrate 11 has a high stress depression effect.

Moreover, when comparing the wiring board assembly 1A of the simulation No. 11 with the wiring board assembly 1B of the simulation No. 12, it can be confirmed that the wiring board assembly 1B of the simulation No. 12 has a high stress depression effect.

When focusing on the results of the simulations No. 4, No. 5, No. 7, No. 8, and No. 10 of FIG. 10, it can be confirmed that pressure resistance with respect to stresses of the solder bumps 16 is sufficient in the wiring board assembly 1 according to the first embodiment. Moreover, when focusing on the result of the simulation No. 11, it can be confirmed that pressure resistance with respect to stresses of the solder bumps 16 is sufficient in the wiring board assembly 1A according to the second embodiment. Moreover, when focusing on the result of the simulation No. 12, it can be confirmed that pressure resistance with respect to stresses of the solder bumps 16 is sufficient in the wiring board assembly 1B according to the third embodiment. Moreover, when focusing on the result of the simulation No. 13, it can be confirmed that pressure resistance with respect to stresses of the solder bumps 16 is sufficient in the wiring board assembly 1C according to the fourth embodiment.

In the embodiments, SUS (Young's modulus: about 200 GPa) and alumina (Al₂O₃, Young's modulus: about 400 GPa) having high Young's modulus materials have been illustrated as the stiffening member 40 (40A, 40B, 40C). However, as the stiffening member 40 (40A, 40B, 40C), there may be used silicon carbide (SiC, Young's modulus: about 430 GPa), silicon nitride (Si₃N₄, Young's modulus: about 280 GPa), aluminum nitride (AlN, Young's modulus: about 350 GPa), nickel (Young's modulus: about 220 GPa), or tin (Young's modulus: about 500 GPa).

Moreover, in the embodiments, silicone rubber (Young's modulus: about 4 MPa to 40 MPa) having low Young's modulus materials has been illustrated as the buffering member 17. However, there may be used ABS (Acrylonitrile Butadiene Styrene) resin (Young's modulus: about 2000 MPa), polyimide (Young's modulus: about 3000 MPa), or the like.

In the embodiments, specific numeric values have been illustrated. However, it is obvious that the embodiments are not limited to these numeric values.

As described above, according to an aspect of the present invention, pressure resistance with respect to stress of solder joints and long-term reliability are improved.

All examples and conditional language recited herein are intended for pedagogical purposes of aiding the reader in understanding the invention and the concepts contributed by the inventor to further the art, and are not to be construed as limitations to such specifically recited examples and conditions, nor does the organization of such examples in the specification relate to a showing of the superiority and inferiority of the invention. Although the embodiments of the present invention have been described in detail, it should be understood that the various changes, substitutions, and alterations could be made hereto without departing from the spirit and scope of the invention.

What is claimed is:

1. A wiring board comprising:
an insulating substrate that includes at least one insulating layer;
a wiring layer that is held in the insulating substrate and forms wiring; and
a restraint member that is placed within a range of a thickness of the insulating substrate and of which a thermal expansion coefficient is smaller than thermal expansion coefficients of the wiring and the insulating substrate.

2. The wiring board according to claim 1, further comprising a pad that is located on the insulating substrate and mounts thereon a component,
wherein the restraint member is placed on a straight line that extends from the pad in a thickness direction of the insulating substrate.

3. The wiring board according to claim 2, wherein the thermal expansion coefficient of the insulating substrate is larger than the thermal expansion coefficient of the component.

4. The wiring board according to claim 1, wherein the restraint member is placed on a straight line that extends from an angular portion of a polygonal component in a thickness direction of the insulating substrate.

5. The wiring board according to claim 1, wherein
the insulating substrate is divided into a plurality of insulating layers by the wiring layer, and
the restraint member is placed, among the plurality of insulating layers, in at least one the insulating layer within a range of a thickness of the at least one insulating layer.

6. The wiring board according to claim 4, further comprising a buffering member that is placed between the restraint member and the insulating substrate in which the restraint member is placed and that has a Young's modulus lower than the Young's modulus of the restraint member.

7. The wiring board according to claim 1, wherein
the insulating substrate is divided into a plurality of insulating layers by the wiring layer, and
the restraint member is placed across the plurality of insulating layers.

8. The wiring board according to claim 1, wherein a Young's modulus of the restraint member is higher than Young's modulus of the insulating substrate and the wiring.

9. A method for manufacturing a wiring board, comprising:
forming a concave portion in an insulating substrate;
placing a restraint member in the concave portion, of which a thermal expansion coefficient is smaller than the thermal expansion coefficient of the insulating substrate and a thickness is not more than a depth of the concave portion; and
forming wiring on the insulating substrate, of which the thermal expansion coefficient is larger than the thermal expansion coefficient of the restraint member.

10. The method for manufacturing the wiring board according to claim 9, wherein the placing includes placing the restraint member of which the thickness is smaller than the depth of the concave portion and then covering a surface of the restraint member with an insulator.

11. The method for manufacturing the wiring board according to claim 9, further comprising forming a pad, which mounts thereon a component, in an area on the restraint member of a surface of the insulating substrate.

12. A wiring board assembly comprising:
a wiring board including:
an insulating substrate that includes at least one insulating layer;
a wiring layer that is held in the insulating substrate and forms wiring;
a pad that is formed on the insulating substrate; and
a restraint member that is placed within a range of a thickness of the insulating substrate and of which a thermal expansion coefficient is smaller than thermal expansion coefficients of the wiring and the insulating substrate; and
a component that is mounted on the pad.
